(19) United States
(12) Patent Application Publication
(10) Pub. No.: US 2014/0118709 A1
(43) Pub. Date: May 1, 2014

(54) HOLDING APPARATUS, LITHOGRAPHY APPARATUS, AND METHOD OF MANUFACTURING ARTICLE

(71) Applicant: CANON KABUSHIKI KAISHA, Tokyo (JP)

(72) Inventors: Akira Morohashi, Utsunomiya-shi (JP); Yuji Maehara, Saitama-shi (JP)

(73) Assignee: CANON KABUSHIKI KAISHA, Tokyo (JP)

(21) Appl. No.: 14/050,770

(22) Filed: Oct. 10, 2013

(30) Foreign Application Priority Data
Oct. 26, 2012 (JP) 2012-237269

(51) Int. Cl. G03F 7/20

(52) U.S. Cl. CPC G03F 7/70875
USPC 355/30; 355/77

(57) ABSTRACT

The present invention provides a holding apparatus which includes a base having, on a surface thereof, a convex portion for supporting a back surface of a substrate and a containing portion for containing a liquid, and supports the substrate via the convex portion and the liquid, the apparatus including a heat storage structure including a latent heat storage member configured to store heat transferred from the substrate, and arranged in the containing portion, and a member configured to exert, to the heat storage structure, a force in a first direction from the base to the substrate.

### BACKGROUND OF THE INVENTION

1. Field of the Invention

The present invention relates to a holding apparatus, a lithography apparatus, and a method of manufacturing an article.

2. Description of the Related Art

In an EUV (Extreme Ultraviolet) exposure apparatus which has been developed as a next-generation semiconductor manufacturing apparatus or a drawing apparatus using a charged particle beam (electron beam), a substrate is exposed in a vacuum atmosphere. In a vacuum atmosphere, the heat is not transferred by convection, and thus tends to accumulate in an object. For the EUV exposure apparatus or drawing apparatus, a measure against heat (cooling of an object) is one of important development elements.

To cool a substrate to be processed by the EUV exposure apparatus or drawing apparatus, for example, a technique of sealing a gas between the substrate and a holding portion (a chuck or the like) for holding the substrate to accelerate heat transfer from the substrate to the holding portion is used. In recent years, it has been required to further accelerate heat transfer to improve a resolution or overlay accuracy. International Patent Publication No.2009/011574 proposes a holding apparatus for holding a substrate by sealing a liquid between the substrate and a holding portion. This holding apparatus holds the substrate by the holding portion using the fact that the layer of the liquid is set at a negative pressure with respect to a vacuum atmosphere.

The holding portion preferably has an increased heat capacity to reduce a change in temperature but it is not preferable to increase the volume (size) of the holding portion. To cope with this, Japanese Patent Laid-Open No. 2009-545157 proposes a holding apparatus using a latent heat storage member, the phase of which changes. This holding apparatus increases a heat amount (heat transfer amount) transferred from a substrate to the latent heat storage member by a heat storage structure including a high heat conducting member and the latent heat storage member.

In the conventional technique, however, it is not always possible to obtain a sufficient heat transfer amount for the resolution or overlay accuracy recently required. Especially in the EUV exposure apparatus or drawing apparatus, the substrate is irradiated with high-energy EUV light or charged particle beam, and thus the heat amount that accumulates in the substrate increases, thereby worsening the problem associated with the heat transfer amount.

### SUMMARY OF THE INVENTION

The present invention provides, for example, a holding apparatus advantageous to transfer of heat from a substrate.

According to one aspect of the present invention, there is provided a holding apparatus which includes a base having, on a surface thereof, a convex portion for supporting a back surface of a substrate and a containing portion for containing a liquid, and supports the substrate via the convex portion and the liquid, the apparatus including a heat storage structure including a latent heat storage member configured to store heat transferred from the substrate, and arranged in the containing portion, and a member configured to exert, to the heat storage structure, a force in a first direction from the base to the substrate.

Further features of the present invention will become apparent from the following description of exemplary embodiments with reference to the attached drawings.

### BRIEF DESCRIPTION OF THE DRAWINGS

FIG. 1 is a schematic view showing the arrangement of a lithography apparatus according to an aspect of the present invention.

FIGS. 2A and 2B are schematic views showing the arrangement of a holding apparatus in the lithography apparatus shown in FIG. 1.

FIG. 3 is a schematic view showing another arrangement of the heat storage structure of the holding apparatus in the lithography apparatus shown in FIG. 1.

### DESCRIPTION OF THE EMBODIMENTS

Preferred embodiments of the present invention will be described below with reference to the accompanying drawings. Note that the same reference numerals denote the same members throughout the drawings, and a repetitive description thereof will not be given.

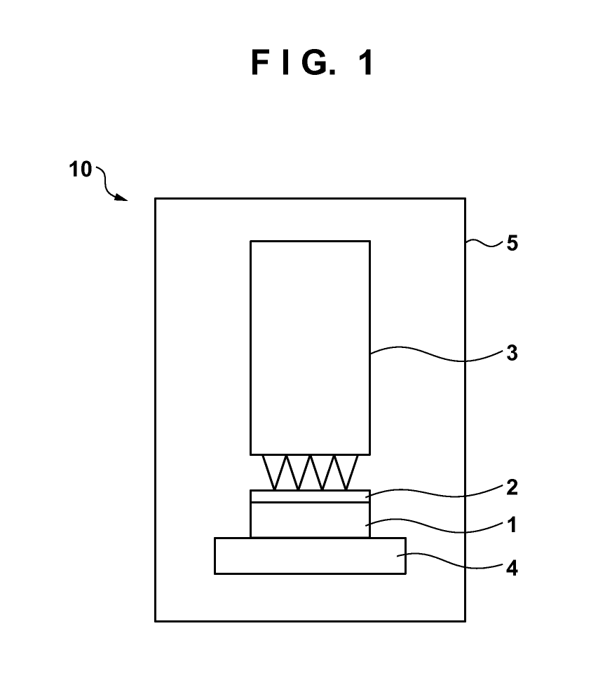

FIG. 1 is a schematic view showing the arrangement of a lithography apparatus 10 according to an aspect of the present invention. The lithography apparatus 10 forms (transfers) a pattern on a substrate. In this embodiment, the lithography apparatus 10 is implemented as a drawing apparatus which includes a charged particle optical system, and draws a pattern on a substrate with a charged particle beam via the charged particle optical system to form the pattern on the substrate. The charged particle beam includes an electron beam and ion beam. The lithography apparatus 10 is not limited to the drawing apparatus, and may be an exposure apparatus such as an EUV exposure apparatus. The exposure apparatus includes a projection optical system, and exposes a substrate via the projection optical system to form a pattern on the substrate. Furthermore, the lithography apparatus 10 may be an imprint apparatus which shapes an imprint material (a resin or the like) on a substrate using a mold to form a pattern on the substrate.

The lithography apparatus 10 includes a charged particle optical system 3, a stage apparatus 4, and a vacuum chamber 5, as shown in FIG. 1. In the lithography apparatus 10, to draw a pattern with a charged particle beam in a vacuum atmosphere, the charged particle optical system 3 and stage apparatus 4 are accommodated in the vacuum chamber 5.

The charged particle optical system 3 includes, for example, an electrostatic lens, collimator lens, aperture array, blanker array, stopping aperture array, and deflector. The charged particle optical system 3 guides a charged particle beam from a charged particle source (not shown) onto a substrate 2 to draw a pattern on it.

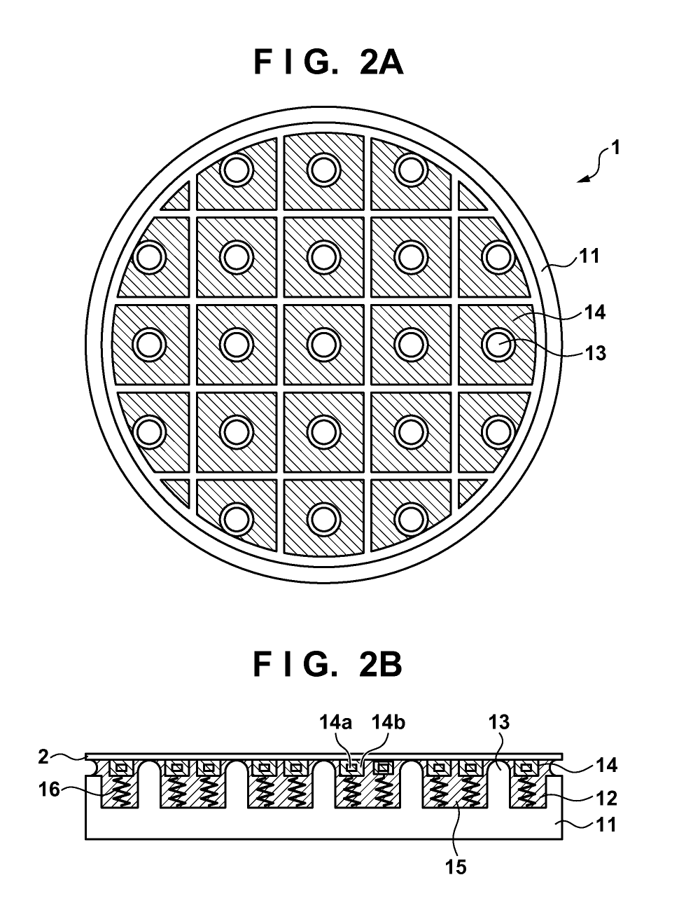

The stage apparatus 4 is configured to be movable to position the substrate 2 with respect to the charged particle optical system 3, and includes a holding apparatus 1 for holding the substrate 2. FIGS. 2A and 2B are schematic views showing the arrangement of the holding apparatus 1. FIG. 2A is a plan view showing the holding apparatus 1, and FIG. 2B is a sectional view showing the holding apparatus 1. The holding apparatus 1 includes a base 11 which has, on its surface, convex portions 13 for supporting the back surface of the substrate 2 and concave portions (containing portions) 15 for containing a liquid 12. The holding apparatus 1 holds the substrate 2 via the convex portions 13 and liquid 12.

The liquid 12 (for example, water) selected in consideration of the wettability (lyophilic property), the heat conductivity, the influence on the use environment, and the like of the substrate 2 and base 11 is supplied to the concave portions 15, which are then filled with the liquid 12. Since the surface tension (capillary pressure) of the liquid 12 in the inward direction acts on the surface (liquid surface) on the substrate side of the liquid 12, the substrate 2 is pressed against the convex portions 13 (base 11) by a pressure (differential pressure) corresponding to the difference between the atmospheric pressure around the liquid 12 and that of the liquid 12. At this time, the pressing force by the capillary pressure and the reaction force acting between the substrate 2 and the convex portions 13 are in balance, and a frictional force is generated between the substrate 2 and the convex portions 13. The substrate 2 is, therefore, held on the convex portions 13 without shifting to one side. Note that the liquid 12 contributes to not only the generation of the force for holding the substrate 2 but also reduction of heat deformation of the substrate 2 by transferring using the heat conductivity the heat that acts on the substrate 2 upon irradiation (that is, drawing) with a charged particle beam to the base 11.

Heat storage structures 14 are respectively arranged in the concave portions 15 so as to be covered by the liquid 12. Each heat storage structure 14 is a structure (composite member) which includes a latent heat storage member 14a for storing the heat transferred from the substrate 2 (via the liquid 12), and a heat conducting member 14b including the latent heat storage member 14a for conducting the heat to the latent heat storage member 14a. The heat transferred from the substrate 2 to the liquid 12 is stored in the latent heat storage members 14a of the heat storage structures 14, thereby reducing a change in temperature of the substrate 2 (that is, reducing heat deformation of the substrate 2).

The latent heat storage member 14a is made of a material whose phase changes from a solid into a liquid upon storing heat, whose temperature does not change upon storing the heat, and whose heat storage amount per unit volume is large, such as calcium chloride hydrate, sodium sulfate hydrate, or paraffin. Note that the material of the latent heat storage member 14a need only be a material, the phase of which changes, and is not limited to the above-described ones. The heat conducting member 14b is made of a metal, ceramics, carbon fiber, resin, or the like.

An application member 16 applies (exerts), to the heat storage structure 14 contained in the concave portion 15, a force in the upward direction (first direction) from the base 11 to the substrate 2, thereby keeping the heat storage structure 14 arranged in the concave portion 15 in close contact with (the back surface of) the substrate 2. In other words, the application member 16 applies, to the heat storage structure 14, a force in a direction from the base 11 to the substrate 2. The application member 16 is coupled to the heat storage structure 14, and the buoyancy that acts on the heat storage structure 14 and application member 16 in the liquid is larger than the gravity that acts on them. The application member 16 includes a coil spring (elastic member), one end (lower end) of which is connected to the concave portion 15 and the other end (upper end) of which is connected to the heat storage structure 14. The coil spring serving as the application member 16 is configured so that its natural length is longer than the distance from the lower end to the upper end (that is, the depth of the concave portion 15) when the holding apparatus 1 holds the substrate 2. Therefore, when the holding apparatus 1 holds the substrate 2, a force proportional to the difference between the natural length of the coil spring and the distance from the lower end to the upper end of the coil spring acts on the heat storage structure 14 in the upward direction, and thus the heat storage structure 14 is kept in close contact with the substrate 2. Since, therefore, the interval between the substrate 2 and the heat storage structure 14 becomes small, and the heat amount transferred from the substrate 2 to the heat storage structure 14 becomes large, a sufficient heat transfer amount is ensured between the substrate 2 and the heat storage structure 14, thereby reducing heat deformation of the substrate 2. Note that the application member 16 is not limited to the coil spring as long as it is possible to keep the heat storage structure 14 in close contact with the substrate 2. For example, the application member 16 may include a structure which keeps the heat storage structure 14 in close contact with the substrate 2 using buoyancy or a magnetic force.

To prevent the substrate 2 from shifting to one side, the force applied to the heat storage structure 14 by the application member 16 need only be sufficiently smaller than the force for holding the substrate 2, which is generated by the liquid 12 (the pressing force by the capillary pressure). For example, the application member 16 need only be configured to apply the force to the substrate 2 in the upward direction via the heat storage structure 14, which is smaller than the force applied to the substrate 2 in the downward direction (a second direction opposite to the first direction) by the liquid 12. The frictional force generated between the substrate 2 and the convex portion 13 is proportional to a force obtained by subtracting the force applied to the heat storage structure 14 by the application member 16 from the pressing force by the capillary pressure. If, therefore, the force applied to the heat storage structure 14 by the application member 16 is large, the frictional force generated between the substrate 2 and the convex portion 13 decreases, and thus the substrate 2 tends to shift to one side.

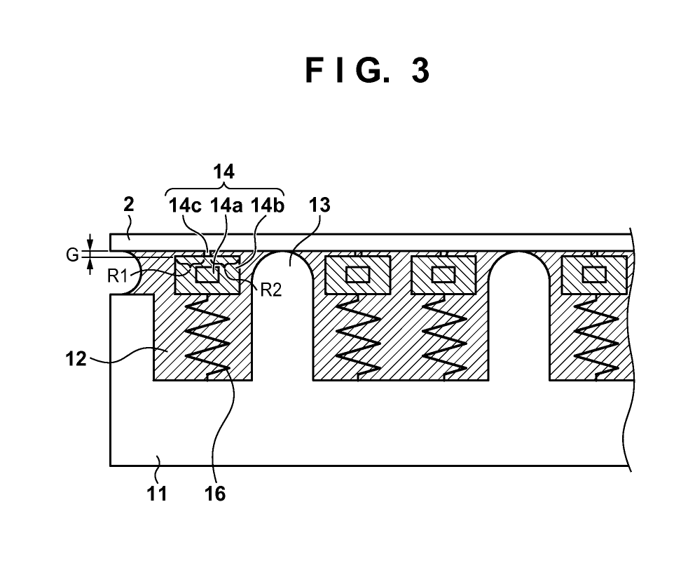

The heat storage structure 14 may include, on its surface on the substrate side, a protrusion 14c contacting the back surface of the substrate 2, as shown in FIG. 3. FIG. 3 is a schematic view showing another arrangement of the heat storage structure 14. If the application member 16 applies a force to the heat storage structure 14, the protrusion 14c abuts against the back surface of the substrate 2 to form a gap G filled with the liquid 12 between the back surface of the substrate 2 and a region R1 of the surface on the substrate side of the heat storage structure 14 except for the protrusion 14c. The gap G between the back surface of the substrate 2 and the region R1 of the surface on the substrate side of the heat storage structure 14 (that is, the thickness of the liquid 12 with which the gap G is filled) depends on the height of the protrusion 14c.

To obtain a force for pressing the substrate 2 against the convex portions 13, the liquid 12 needs to contact the back surface of the substrate 2, and needs to be continuous from a meniscus portion which generates the capillary pressure. To attain this objective, in this embodiment, the contact area between the substrate 2 and the liquid 12 is made large by providing the protrusion 14c on the surface on the substrate side of each heat storage structure 14, thereby ensuring a sufficient pressing force. Furthermore, since the liquid 12 with which the gap G is filled can maintain the continuity by the protrusion 14c, it is possible to ensure a sufficient pressing force. Since the interval between the substrate 2 and the heat storage structure 14 can be made small by appropriately determining the height of the protrusion 14c, it is possible to ensure a sufficient heat transfer amount between the substrate 2 and the heat storage structure 14, thereby reducing heat deformation of the substrate 2, as described above.

The number of protrusions 14c provided on the surface on the substrate side of the heat storage structure 14 need only be one or more. The protrusion 14c may be surface roughness (uneven surface) when processing the surface on the substrate side of the heat storage structure 14, or may have a structure including a number of grooves (a surface defined by the grooves) as long as part of the protrusion 14c can contact the back surface of the substrate 2.

As described above, the holding apparatus 1 can keep the heat storage structure 14 in close contact with the substrate 2 to sufficiently store the heat transferred from the substrate 2, thereby allowing reduction of heat deformation of the substrate 2. The lithography apparatus 10 can, therefore, achieve a good resolution or overlay accuracy, thereby providing an article such as a high-quality device (semiconductor device or liquid crystal display device) with a high throughput and good economic efficiency.

A method of manufacturing an article according to the embodiment of the present invention is preferable for manufacturing articles including a micro device such as a semiconductor device and an element having a microstructure. The manufacturing method includes a step of forming a pattern on a substrate coated with the photosensitizing agent (a step of drawing a pattern on a substrate) using the lithography apparatus 10. The manufacturing method can also include a step of developing the substrate having the pattern formed on it in the forming step. Furthermore, the manufacturing method can include subsequent known steps (for example, oxidation, film formation, vapor deposition, doping, planarization, etching, resist removal, dicing, bonding, and packaging) after the forming step. The method of manufacturing an article according to this embodiment is more advantageous in terms of at least one of the performance, quality, productivity, and manufacturing cost of an article than the conventional method.

The present invention is applicable not only to a lithography apparatus but also to an apparatus for performing processing other than drawing and exposure for a substrate set in a vacuum atmosphere. The present invention is also applicable to an apparatus for performing processing for a substrate set in an atmosphere (for example, air) other than a vacuum atmosphere.

While the present invention has been described with reference to exemplary embodiments, it is to be understood that the invention is not limited to the disclosed exemplary embodiments. The scope of the following claims is to be accorded the broadest interpretation so as to encompass all such modifications and equivalent structures and functions.

This application claims the benefit of Japanese Patent Application No. 2012-237269 filed on Oct. 26, 2012, which is hereby incorporated by reference herein in its entirety.

1. A holding apparatus which includes a base having, on a surface thereof, a convex portion for supporting a back surface of a substrate and a containing portion for containing a liquid, and supports the substrate via the convex portion and the liquid, the apparatus comprising:
a heat storage structure including a latent heat storage member configured to store heat transferred from the substrate, and arranged in the containing portion; and
a member configured to exert, to the heat storage structure, a force in a first direction from the base to the substrate.

2. The apparatus according to claim 1, wherein
the heat storage structure includes a protrusion which contacts the back surface due to the force, and
the protrusion forms a gap filled with the liquid between the heat storage structure and the back surface with the protrusion contacting the back surface.

3. The apparatus according to claim 1, wherein the force exerted to the substrate in the first direction by the member via the heat storage structure is smaller than a force exerted to the substrate in a second direction opposite to the first direction by the liquid.

4. The apparatus according to claim 1, wherein the member includes a coil spring, one end of which is connected to the containing portion and the other end of which is connected to the heat storage structure.

5. The apparatus according to claim 1, wherein the member is coupled to the heat storage structure, and a buoyancy force exerted to the heat storage structure and the member in the liquid is larger than a gravitational force exerted to the heat storage structure and the member.

6. The apparatus according to claim 1, wherein the heat storage structure includes a heat conducting member covering the latent heat storage member and configured to conduct heat to the latent heat storage member.

7. A lithography apparatus for forming a pattern on a substrate, comprising:
a holding apparatus for holding the substrate, wherein the holding apparatus includes a base having, on a surface thereof, a convex portion for supporting a back surface of a substrate and a containing portion for containing a liquid, and supports the substrate via the convex portion and the liquid, wherein the holding apparatus further comprises:
a heat storage structure including a latent heat storage member configured to store heat transferred from the substrate, and arranged in the containing portion; and
a member configured to exert, to the heat storage structure, a force in a first direction from the base to the substrate.

8. The apparatus according to claim 7, further comprising
a charged particle optical system,
wherein the pattern is formed on the substrate with a charged particle beam via the charged particle optical system.

9. The apparatus according to claim 7, further comprising
a projection optical system,
wherein the pattern is formed on the substrate with light via the projection optical system.

10. A method of manufacturing an article, the method comprising:
forming a pattern on a substrate using a lithography apparatus; and
processing the substrate on which the pattern has been formed,
wherein the lithography apparatus includes a holding apparatus for holding the substrate, and the holding apparatus includes a base having, on a surface thereof, a convex portion for supporting a back surface of the substrate and a containing portion for containing a liquid, and supports the substrate via the convex portion and the liquid, the holding apparatus including:
a heat storage structure including a latent heat storage member configured to store heat transferred from the substrate, and arranged in the containing portion; and
a member configured to exert, to the heat storage structure, a force in a first direction from the base to the substrate.
